(19) United States
(12) Patent Application Publication
(10) Pub. No.: US 2010/0309940 A1
(43) Pub. Date: Dec. 9, 2010

(54) HIGH POWER LASER PACKAGE WITH VAPOR CHAMBER

(76) Inventor: Hsing-Chung Lee, Calabasas, CA (US)

Correspondence Address: ROBERT A. PARSONS, 4000 N. CENTRAL AVENUE, SUITE 1220, PHOENIX, AZ, 85012, US

(21) Appl. No.: 12/478,190

(22) Filed: Jun. 4, 2009

(51) Int. Cl. H01S 3/04; F28D 15/04; F28F 7/00; H05K 7/20

(52) U.S. Cl. 372/34; 165/104.26; 165/185

(57) ABSTRACT

A heat spreader structure includes a high power laser with an epi side and an emitting facet. A vapor chamber includes a housing defining an inner vapor cavity and a wick positioned in the vapor cavity to define an evaporation area on one side of the cavity, a condensation area on an opposite side of the cavity, and fluid communication between the condensation area and the evaporation area. A space defined between the evaporation area and the condensation area. The wick includes a porous powder sintered to inner surfaces of the sealed cavity to hold the porous powder in position. The epi side of the laser is coupled to the one side of the vapor chamber and heat removal mechanism is coupled to the opposite side of the cavity.

### FIELD OF THE INVENTION

This invention generally relates to a heat spreaders including vapor chambers as a component thereof and more specifically to heat spreaders for use with high power laser packages.

### BACKGROUND OF THE INVENTION

One specific application for heat spreaders in conjunction with relatively high heat sources is in the high power semiconductor laser field. High power semiconductor lasers are replacing flash lamps in pumping solid state lasers and fiber lasers. The solid state laser and fiber laser markets are expanding rapidly by penetrating into laser material processing and laser machining applications and driving the demand for high power semiconductor lasers. The key challenges for high power semiconductor lasers are (1) reliability and (2) catastrophic optical damages (COD). The performance, reliability and COD are closely related to junction temperature. The performance of semiconductor lasers degrades at high temperature due to increasing carrier leakages and enhanced Auger recombinations. The reliability of semiconductor lasers degrades due to enhanced defect generations. The defect generation process is temperature activated with activation energy around 0.7 eV. Ten degrees C. rise in temperature can reduce the lifetime of the laser by half. The catastrophic optical damage is related to temperature through a thermal run-away process. There is more surface recombination near the facet and more heat will be generated leading to high temperature. The differential high temperature leads to current crowding near the facet, which further enhances the heat generation near the facet. This is a positive feedback regenerative process. Removing heat can damp the regenerative process and improve the COD threshold optical power. Therefore, heat removal is an important issue for semiconductor packaging.

There are two configurations for packaging semiconductor lasers, namely epi-up and epi-down. In the epi-up configuration, the backside of the laser die is in contact with the heat spreader. The advantage is that the active junction is far away from the bonding interface to the heat spreader and the stress of the bonding is less critical in affecting the reliability. But the poor thermal conductivity thick (100 microns) laser substrate is between the active junction and the heat spreader and contributes a larger thermal resistance. Therefore, all high power lasers are using the epi-down configuration. In the epi-down configuration, the laser die is mounted to the heat spreader by solder with the front surface in contact with the heat spreader. The active junction is only 2˜3 microns away from the heat spreader. The thermal resistance from the laser material is much smaller. On the other hand, the bonding interface is also only 2˜3 microns away from the active junction and the junction is more susceptible to the stress of the bonding. The stress can lower the activation of the defect generation and result in poor reliability for the same junction temperature. To reduce the stress, the heat spreader has to be thermal expansion matched to the laser. There are trade-offs between thermal conductivity and thermal expansion match. CuW, ALN and BeO are the most popular materials for the heat spreader where the thermal conductivity is less than 200 W/mK. The thermal conductivity of the heat spreader is the most critical property to reduce degradation of and/or improve the performance, reliability and COD of high power semiconductor lasers. The thermal conductivity of solids is limited (most abundant materials have a thermal conductivity less than 400 W/mK). With a finite thermal conductivity, it is necessary to count on the geometric factor to reduce the total spreading resistance. The geometric factor does not favor thin structures (the best geometric factor is a sphere from the heat source). There are reports using fluid to improve the thermal conductivity. Effective conductivity up to 10,000 W/mK have been reported.

It would be highly advantageous, therefore, to remedy the forgoing and other deficiencies inherent in the prior art.

Accordingly, it is an object of the present invention to provide a new and improved heat spreader for use with high power semiconductor lasers and the like.

It is another object of the present invention to provide a new and improved heat spreader including an improved vapor chamber.

It is another object of the present invention to provide an improved vapor chamber for use in heat spreaders applied to high power semiconductor lasers and the like.

### SUMMARY OF THE INVENTION

Briefly, to achieve the desired objects of the instant invention in accordance with a preferred embodiment thereof, provided is a heat spreader structure. The heat spreader structure includes carrier material with one surface designed to be coupled to the epi side of a laser and an opposite surface. The carrier material is selected to substantially match the coefficient of thermal expansion of a laser affixed thereto. A vapor chamber includes a housing defining an inner vapor cavity and a wick positioned in the vapor cavity to define an evaporation area on one side of the cavity, a condensation area on an opposite side of the cavity, and fluid communication between the condensation area and the evaporation area. The wick includes a micro-structure. The carrier material may be either a separate strip of material coupled to the one side of the vapor chamber or it may be formed as a portion of the housing of the vapor chamber. The heat removal mechanism is coupled to the opposite side of the vapor chamber.

The desired objects of the instant invention are further achieved in accordance with an embodiment thereof, including a heat spreader structure. The heat spreader structure includes a high power laser with an epi side and an emitting facet. A vapor chamber includes a housing defining an inner vapor cavity and a wick positioned in the vapor cavity to define an evaporation area on one side of the cavity, a condensation area on an opposite side of the cavity, and fluid communication between the condensation area and the evaporation area. The wick includes a micro-structure. The epi side of the laser is coupled to the one side of the vapor chamber and heat removal mechanism is coupled to the opposite side of the cavity. At least a portion of the one side of the vapor chamber includes material selected to substantially match the coefficient of thermal expansion of the epi side of the laser affixed thereto.

The desired objects of the instant invention are further achieved in accordance with an embodiment including a thin form factor vapor chamber designed for use in a heat spreader structure. The vapor chamber includes a housing with a first member and a second member defining a sealed cavity therebetween. A region adjacent an inner surface of the first member defines an evaporation area within the vapor chamber and a region adjacent an inner surface of the second member defines a condensation area within the vapor chamber. A wick includes a first layer of porous powder overlying the inner surface of the first member, a second layer of porous powder overlying the inner surface of the second member and a third layer of porous powder positioned in fluid communication with the first layer and the second layer. A space is defined between the first, the second, and the third layers of porous powder.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a top perspective view of a heat spreader structure for use with high power semiconductor lasers and the like incorporating a solid copper base;

FIG. 2 is a top plan, simplified of a high power laser illustrating the general layout;

FIG. 3 is a top perspective view of the heat spreader structure of FIG. 1 illustrating the distribution of heat;

FIG. 4 is a top perspective view of a heat spreader structure for use with high power semiconductor lasers and the like incorporating a vapor chamber, in accordance with the present invention;

FIG. 5 is a top perspective view of the heat spreader structure of FIG. 3 illustrating the distribution of heat;

FIG. 6 is a simplified semi-schematic view of a vapor chamber used in the heat spreader of FIG. 4, in accordance with the present invention;

FIG. 7 is a side view of another embodiment of a heat spreader structure in accordance with the present invention; and

FIG. 8 is a side view of another embodiment of a heat spreader structure in accordance with the present invention.

### DETAILED DESCRIPTION OF A PREFERRED EMBODIMENT

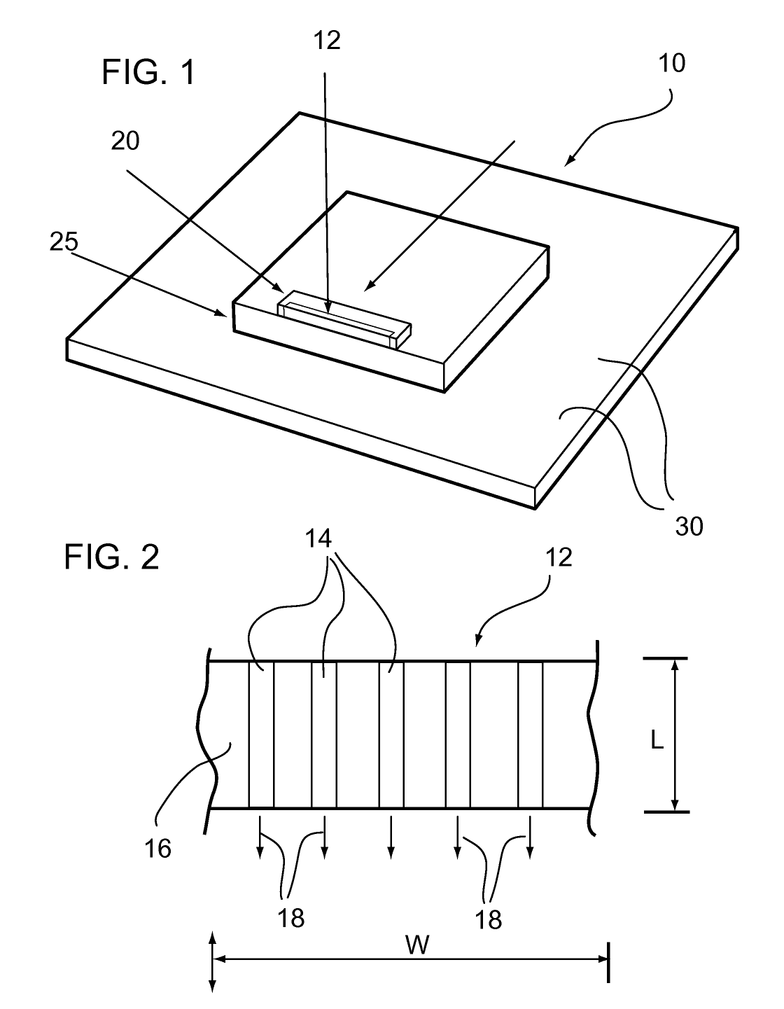

Turning now to the drawings, attention is first directed to FIG. 1, which illustrates a heat spreading structure, generally designated 10, for use with high power semiconductor lasers and the like. Heat spreading structure 10 is being submitted as a baseline or example of the structure involved in heat spreaders for use with high power semiconductor lasers and the like and is not prior art but is simply presented and discussed to develop a basic structure.

Structure 10 includes a GaAs semiconductor laser 12 which is constructed to generate, for example, 100 watts of power. For convenience of understanding, the “heat spreading structure” is considered to include the laser being cooled. It will be understood that the specific power generated depends on the application and the present structure is simply for exemplary purposes. Also, it will be understood that a GaAs semiconductor laser is used in this description as an example but many other types of lasers could be used if desired. Referring additionally to FIG. 2, a simplified top plan view of semiconductor laser 12 is illustrated in more detail to provide a better understanding of the construction and operation. Semiconductor laser 12 includes a plurality of discrete lasers 14 formed in parallel on a common substrate 16. Because these structures are well known in the art, further construction details will not be discussed except to state that laser 12 is positioned in an epi-down configuration in FIGS. 1 and 2. Further, laser 12, in this specific example, is approximately 1-2 mm long (designated L in FIG. 2), 10 mm wide (designated W in FIG. 2) and approximately 2 μm thick between the active junction and the lower or epi surface. Each of the discrete lasers 14 emits downwardly as indicated by arrows 18, in FIG. 2, so that the lower edge of substrate 16 is the front or emitting end of the active junction. For purposes of this disclosure the individual emissions are considered to join and form a single beam emission.

Referring again to FIG. 1, GaAs laser 12 has a thermal conductivity of approximately 55 W/mK and the GaAs substrate has a coefficient of thermal expansion (CTE) of approximately 6 ppm/° C. Laser 12 is mounted epi-down on a carrier 20 constructed of material with a CTE that reduces the stress by being more closely matched to the CTE of laser 12. The problem that arises is that the thermal conductivity normally goes down as the CTE more closely matches the CTE of laser 12. In this embodiment, for example, carrier 20 is constructed of CuW, which has a thermal conductivity of approximately 175 W/mK and a CTE of approximately 6 ppm/° C. Other materials that can be used for carrier 20 are AlN and BeO. In each of these materials the CTE more closely matches laser 12 but the thermal conductivity is still relatively good. Carrier 20 is approximately 11 mm long by 3 mm wide by 1 mm thick. The epi-down surface of laser 12 is generally soldered directly to the upper surface of carrier 20.

Carrier 20 is mounted on an upper surface of a heat absorbing and spreading element 25. Heat spreading element 25 is formed of some abundant material, such as copper, having a thermal conductivity below 400 W/mK. In this specific embodiment heat spreading element 25 is formed of substantially pure copper with a thermal conductivity of approximately 390 W/mK. Heat spreading element 25 is a rectangular block approximately 25 mm long, 25 mm wide and 7 mm thick. As understood by artisans, copper is relatively inexpensive, with a relatively good thermal conductivity but a CTE of approximately 17 ppm/° C. Heat spreading element 25 is generally mounted on some nearly infinite heat absorbing structure, such as thermal electric coolers (TECs) 30, included to provide a sink for heat. TECs 30 hold the lower surface of spreading element 25 at approximately a constant temperature, in this embodiment 25 C.

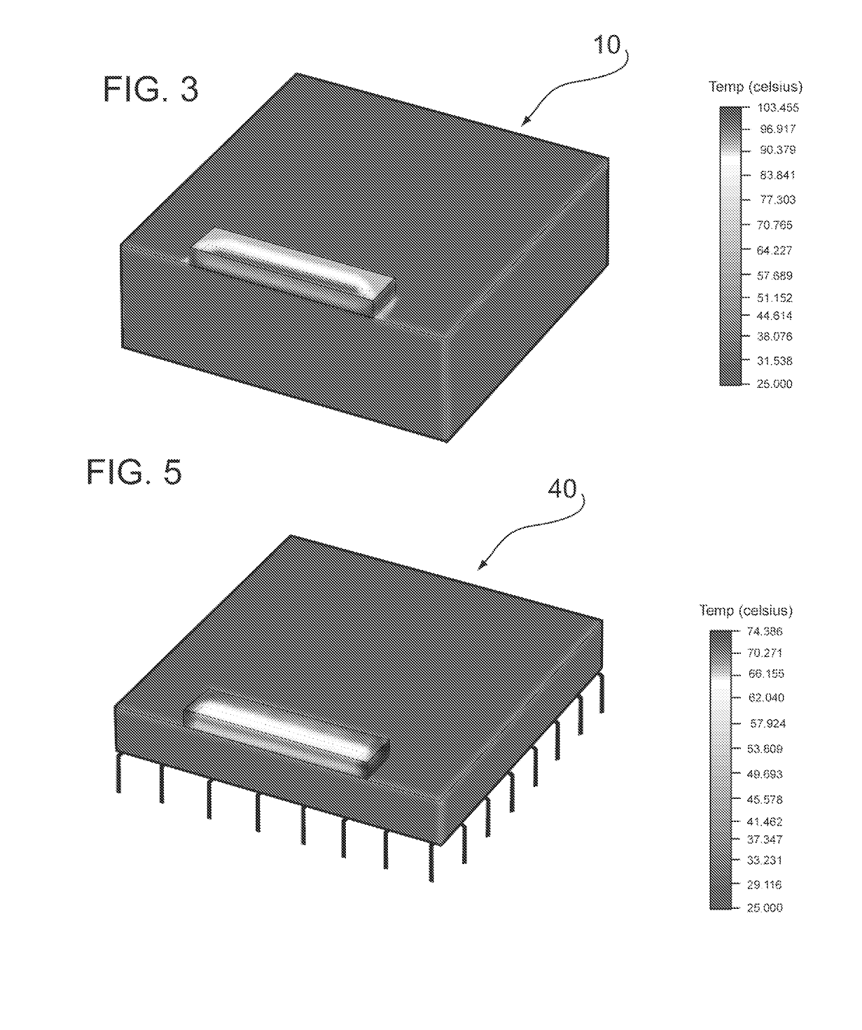

Referring additionally to FIG. 3, baseline structure 10 is illustrated with a temperature graph showing the temperature differential across structure 10 from the relatively constant 25° C. at the lower surface (i.e. the surface of TECs 30) to the upper surface (approximately the junction temperature) of laser 12. Because copper heat spreading element 25 has a thermal conductivity of approximately 390 W/mK the temperature at the upper surface (approximately the junction temperature) of laser 12 is approximately 103.455° C. This temperature is relatively high and contributes substantially to the degradation of the performance, reliability and COD of high power of laser 12. As explained above, ten degrees C. rise in temperature can reduce the lifetime of the laser by half. Thus, any reduction in the temperature at the upper surface (approximately the junction temperature) of laser 12 will substantially improve performance, reliability and COD of high power of laser 12.

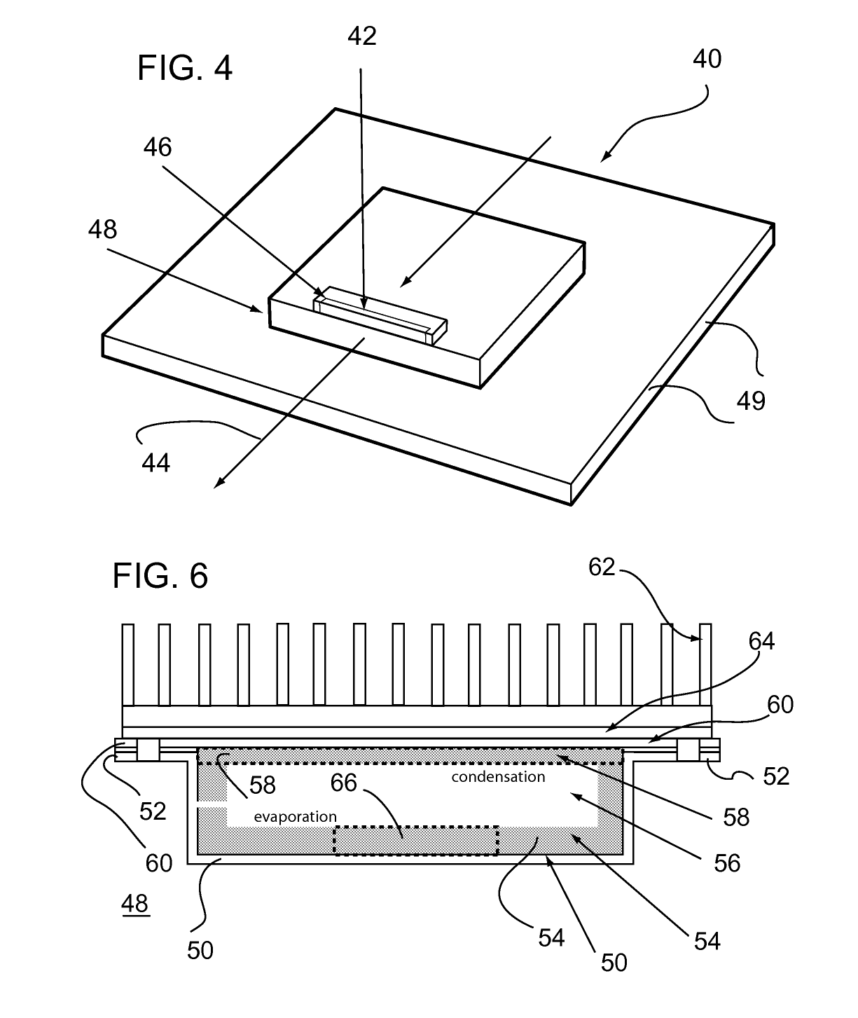

Turning now to FIG. 4, a heat spreader structure 40 for use with high power semiconductor lasers and the like is illustrated, in accordance with the present invention. Structure 40 includes a GaAs semiconductor laser 42 which is constructed to generate, for example, 100 watts of power. For purposes of this disclosure it will be understood by those skilled in the art the term “high power laser” generally refers to any laser with sufficient power to require external cooling apparatus. It will be understood that GaAs semiconductor laser 42 is included to provide a comparison with baseline structure 10 and the specific laser utilized and the power generated depends primarily on the application. As described in conjunction with FIGS. 1 and 2, semiconductor laser 42 includes a plurality of discrete lasers formed in parallel on a common substrate. Also, for maximum temperature reduction and to further the comparison with baseline structure 10, laser 42 is positioned in an epi-down configuration. Further, laser 12, in this specific example, is approximately 1-2 mm long, 10 mm wide and approximately 2 μm thick between the active junction and the lower or epi surface. Each of the discrete lasers 14 emits in a direction indicated by arrow 44, in FIG. 4. For purposes of this disclosure the individual emissions are considered to join and form a single beam emission.

GaAs laser 42 has a thermal conductivity of approximately 55 W/mK and the GaAs substrate has a coefficient of thermal expansion (CTE) of approximately 6 ppm/° C. Laser 42 is mounted epi-down on a carrier 46 constructed of material with a CTE that reduces the stress by being more closely matched to the CTE of laser 42. In this embodiment, for example, carrier 46 is constructed of CuW, which has a thermal conductivity of approximately 175 W/mK and a CTE of approximately 6 ppm/° C. Other materials that can be used for carrier 46 are lIN and BeO. In each of these materials the CTE more closely matches laser 42 but the thermal conductivity is still relatively good. Carrier 46 is approximately 11 mm long by 3 mm wide by 1 mm thick. The epi-down surface of laser 42 is generally soldered directly to the upper surface of carrier 46. Thus, any difference in the coefficient of thermal expansion between laser 42 and carrier 46 results directly in undesirable stress on laser 42.

Carrier 46 is mounted on an upper surface of a vapor chamber structure 48. For purposes of this invention, it should be understood that vapor chamber structure 48 includes a chamber with fluid therein and a space for the evaporation and condensation of the fluid. Heat is transferred to a surface of vapor chamber structure 48 in contact with the lower surface of carrier 46, which causes evaporation of fluid within the chamber. A substantial amount of the heat transferred to the surface is used or absorbed in the evaporation process. The evaporated fluid moves to an opposite surface of vapor chamber structure 48 where it condenses. A substantial amount of the heat transferred to the fluid in the evaporation process is transferred to the opposite surface in the condensation process. The thermal conductivity of vapor chamber structure 48 is substantially greater than the thermal conductivity of rectangular copper block 25 (i.e. approximately 390 W/mK) and, therefore, substantially reduces the temperature of the junction of GaAs laser 42. Vapor chamber structure 48 is generally mounted on some nearly infinite heat removal structure, such as thermal electric coolers (TECs) 49, included to provide a sink for heat.

Referring additionally to FIG. 6, a specific embodiment of vapor chamber structure 48 is illustrated. Vapor chamber structure 48 includes a base stamping 50 formed as a box or depression, open at the top (in FIG. 6) and including an outwardly directed flange 52 extending around the perimeter of the open top. A base wick 54 is distributed inside the box (base stamping 50), along the lower surface and the sides. Base wick 54 is preferably formed to define an opening or vapor space 56 in the middle area of the box (base stamping 50). A cover wick 58 is distributed across the top of the box (base stamping 50) and a cover stamping 60 is affixed to the flange 52 of base stamping 50 by some convenient means, such as a brazing alloy 62, solder, welding, etc. Base stamping 50 and cover stamping 60 form a sealed housing and it will be understood that at least the names may be reversed if desired for any reason, i.e. the cover may define the evaporation area and the base may define the condensation area. Here it will be understood that cover wick 58 can be affixed to the under surface of cover stamping 60 and correctly positioned by the positioning of cover stamping 60 or cover wick 58 can be distributed in base stamping 50 before cover stamping 60 is assembled in position. Some heat distributing element 62, such as fins, TECs 49, etc. is attached to the upper or outer surface of cover stamping 60 by some convenient means, such as solder 64. Heat distributing element 62 with fins is illustrated as one means of distributing the heat and it will be understood that thermal electric coolers (TECs) 49 (see FIG. 4) replace heat distributing element 62 including the fins.

Basically, vapor chamber structure 48 is composed of a bottom plate, a top plate, and a water loading tube. All three components are assembled together to form a sealed chamber after the water loading tube is sealed. The outwardly directed flange around the periphery (flange 52 in FIG. 6) on either one of the top, bottom or both plates provides the structure to seal all components. Inside the chamber, an evaporation area or region is defined by the heat source, in this example, semiconductor laser 42. More specifically, the evaporation area or region is located adjacent the top or bottom plate, whichever the laser is mounted on. A micro-structure (hereinafter referred to as a wick or wicks) with surface roughness is used to promote evaporation. In the remaining cooler regions or area, water condenses and circles back to the evaporation region via a capillary effect. The capillary effect can be created with a microstructure or wick defining pores or openings (hereinafter ‘porous network’ or ‘opening channels’) therein. The porous network or opening channels can be created for example, by thin layers of Cu powder, Cu mesh, or etched channels on one of the top and bottom plates or both. Finally, in the preferred embodiment, low oxygen water is loaded into the vapor chamber, before sealing, to operate as the media to remove heat.

More specifically, in the operation of vapor chamber structure 48 and especially in conjunction with heat spreader structure 40, the orientation of vapor chamber structure 48 as illustrated in FIG. 6 is reversed or flipped over. The lower surface of carrier 46 is affixed to the outer surface of base stamping 50 in a central area thereof. The internal area immediately adjacent to the contact area of carrier 46 is illustrated in broken lines in FIG. 6 and is designated evaporation area or region 66. Thus, heat is conducted from carrier layer 46, through base stamping 50 and absorbed directly by evaporation of fluid in base wick 54 in region 66. The evaporated fluid travels as a vapor to cover wick 58 on cover stamping 60 where it condenses, thereby transferring heat to cover stamping 60 and then to heat distributing element 62. To this end it will be recognized that cover stamping 60 will generally be constructed of high thermal conductivity material (e.g. copper, etc.). The condensed fluid is then conducted (capillary effect) through the sides of base wick 54 (or any part of wick 54 touching wick 58) back to evaporation area 66 where the process is repeated. Base stamping 50 and cover stamping 60 cooperate to form a sealed housing with the names selected for best understanding. It will be understood, that the names “base” and “cover” are selected for purposes of this description and may be reversed (i.e. they are completely interchangeable) if desired for any reason.

One major advantage of vapor chamber structure 48 is the wick structure. To provide a maximum evaporation/condensation operation, which results in maximum thermal conductivity, the wick structure is a micro-structure resulting in a highly porous structure. Several tradeoffs are present that require some consideration. For example, the wick has to be as thin as possible to reduce conduction resistance, however, wicks for high power application have to be thicker to be able to supply enough fluid. Wicks with optimal parameters have a high thermal conductivity and high liquid permeability. High permeability requires high porosity; however, high porosity results in low thermal conductivity of the wick. However, in any instance vapor chamber structure 48 has a thin form factor because fluid and the properties of evaporation and condensation are used. To illustrate the thin form factor, the dimensions of vapor chamber structure 48 in FIG. 4 are 25 mm long by 25 mm wide by 3 mm thick. Generally, the thickness of vapor chamber structure 48 between the upper and lower surfaces is in a range of approximately 2 mm to 4 mm.

In the embodiment illustrated in FIG. 6 with the dimension described and the materials included, the thermal conductivity is approximately 5000 W/mK. Referring additionally to FIG. 5, heat spreader structure 40 is illustrated with a temperature graph showing the temperature differential across structure 40 from the relatively constant 25° C. at the lower surface (i.e. the surface of TECs 49) to the upper surface (approximately the junction temperature) of laser 42. Because vapor chamber structure 48 has a thermal conductivity of approximately 5000 W/mK the temperature at the upper surface (approximately the junction temperature) of laser 12 is reduced to approximately 74.386° C. Thus, the junction temperature of laser 42 is reduced by approximately 30° C. and the performance, reliability and COD of high power of laser 42 is substantially improved. Preferably, the micro-structure making up the wick in the present embodiment includes a powder with a particle size in a range of approximately 30 μm to approximately 200 μm, and preferably approximately 80 μm. The wick thickness is in a range of approximately 0.1 mm to approximately 1 mm and preferably approximately 0.4 mm with a high dry-out heat flux of ˜80 W/cm². The powder is distributed within base stamping 50 and cover stamping 60 and sintered to hold it fixedly in place and fixed to the stampings. Each different powder requires a unique sintering profile (i.e. temperature and time). Some powder shrinkage occurs during the sintering, which must be accounted for to ensure proper contact between base wick 54 and cover wick 58 and a liquid return path from the condensation area to the evaporation area.

It should be understood that vapor chamber structure 48 has a large number of somewhat variable parameters that can be used to affect the overall thermal conductivity. One parameter that affects the overall thermal conductivity is the thickness of carrier 46. Because carrier 46 is immediately adjacent laser 42, and specifically the laser junction, the thickness and type of material is important. Generally, as explained above, there is a tradeoff between the various parameters of carrier 46 to reduce stress on laser 42 as much as possible while providing as high a thermal conductivity as possible or practical. Also, the bottom wall of base stamping 50 is affixed to carrier 46 and should be as thin as possible with as good a thermal conductivity as possible or practical. With a finite thermal conductivity (e.g. baseline structure 10), it is necessary to count on the geometric factor to reduce the total spreading resistance. The geometric factor does not favor thin structures, however, with high effective thermal conductivity, the geometric factor can be sacrificed in favor of the thin form factor.

In some specific applications the thickness of the bottom wall of base stamping 50 may vary. For example, by improving the heat dissipation near the facet of laser 42 (i.e. the emitting surface) differentially, the catastrophic optical damage (COD) of laser 42 can be improved. One method for achieving this differential heat dissipation is to slightly reduce the thickness of the carrier adjacent the front edge or to reduce the CuW (i.e. increase the Cu) adjacent the front edge. The stress will increase slightly but adjacent the facet the stress is less critical in affecting the reliability. Also, because the wick material in base wick 54 and cover wick 58 is porous, the thermal conductivity can vary over small distances (e.g. between adjacent powder particles). It is preferable for the most efficient operation of laser 42 that the temperature is constant along the length of the laser junction (with the exception of immediately adjacent the facet) (see FIG. 2). To this end, carrier 46 and the bottom wall of base stamping 50 can be designed and operate to smooth-out or substantially remove any thermal variations produced by the porous wick.

Some variable parameters include: wick (i.e. micro-structure) type and pore geometry, wick (i.e. micro-structure) thickness and wick-to-stamping bonding strength, as explained above. Some other variable parameters include: the liquid return path from the condensation area, the vapor space 56 thickness, the vapor level in vapor chamber structure 48, the mass of liquid (generally water but could be other liquids), the liquid (water) quality, etc. Some variable parameters are dependent upon the specific application and include: flatness of vapor chamber structure 48, the heat source area, the power density, dimensions of the various components, heat removal mechanism (i.e. heat transfer coefficient on the condenser area side, TECs 49 in the disclosed embodiment.

In a specifically tailored wick configuration, a high thermal conductivity, small spherical powder is used in evaporation area 66. The small particle size in this area is in a range of approximately 30 μm to approximately 40 μm. A high permeability, large powder size is used elsewhere in the wick. The large particle size in this area is in a range of approximately 100 μm to approximately 200 μm. It will be understood that specific applications can include tailored wicks with a plurality of different powders.

In the described embodiment of heat spreader structure 40, carrier 46 is include to provide a closer match between the CTE of laser 42 and the remaining heat spreading structure. However, in at least some specific applications the material of base stamping 50 can be selected to more closely match the CTE of laser 42. In such embodiments it may be possible to eliminate or substantially reduce carrier 46. Depending upon the match of the CTE between the materials, the thickness of the base stamping may simply be adjusted to reduce stress in laser 42 and to smooth-out or substantially remove any thermal variations produced by the porous wick. For example, in a specific embodiment the base stamping is made of CuW and carrier 46 is eliminated. Thus, rather than carrier material being included in a separate layer, the carrier material is incorporated into the base stamping.

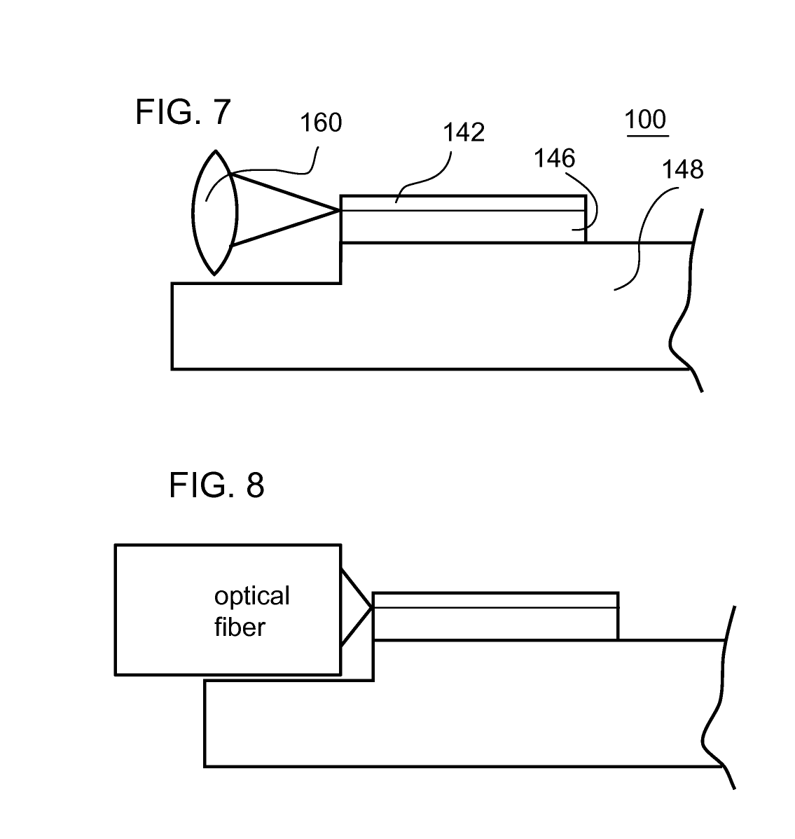

Referring to FIG. 7, another embodiment is illustrated of a heat spreader structure, designated 100, in accordance with the present invention. In the embodiment of FIG. 7 components that are similar to components illustrated in FIG. 4 are designated with similar numbers and a one “1” is added in front to indicate the different embodiment. In this embodiment a lens 160 is included to focus the beam, or beams, from laser 142. Because of the focusing there is no danger that vapor chamber 148 might interfere with the laser beam and, therefore, vapor chamber 148 can be extended forward of the laser facet and carrier 146. This feature can add substantial thermal conductivity because of the additional vapor chamber dimensions. Similarly, an embodiment is illustrated in FIG. 8 in which lens 160 is replaced with an optical fiber. Again, because of the fiber there is no danger that the vapor chamber might interfere with the laser beam and, therefore, the vapor chamber can be extended forward of the laser facet and the carrier.

Thus, a new and improved heat spreader structure for use with high power semiconductor lasers and the like has been disclosed. The new and improved heat spreader includes an improved vapor chamber that is used in place of a rectangular block of copper or the like. Also, a new and improved vapor chamber is disclosed for use in heat spreaders applied to high power semiconductor lasers and the like. By reducing the heat spreading resistance, the high power laser can operate at a high current level reliably giving out high optical power still within improved COD threshold optical power.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A heat spreader structure, the structure comprising:
carrier material having one surface designed to be coupled to a laser and an opposite surface, the carrier material having a coefficient of thermal expansion substantially matching the coefficient of thermal expansion of the laser;
a vapor chamber including a housing defining an inner vapor cavity and a wick positioned in the vapor cavity to define an evaporation area on one side of the cavity, a condensation area on an opposite side of the cavity, a space between the evaporation area and the condensation area and fluid communication between the condensation area and the evaporation area, the wick including a micro-structure;
the carrier material being one of a separate strip of material coupled to the one side of the vapor chamber and being formed as a portion of the housing of the vapor chamber; and
heat removal mechanism coupled to the opposite side of the cavity.

2. A heat spreader structure as claimed in claim 1 wherein the carrier material includes one of CuW, AlN, and BeO.

3. A heat spreader structure as claimed in claim 1 wherein the housing of the vapor chamber includes a first member and a second member defining a sealed cavity therebetween, an inner surface of the first member defining the evaporation area, an inner surface of the second member defining the condensation area, the wick including a first micro-structure overlying the inner surface of the first member, a second micro-structure overlying the inner surface of the second member and a third micro-structure positioned in fluid communication with the first layer and the second layer.

4. A heat spreader structure as claimed in claim 3 wherein the micro-structure includes at least a layer of porous powder.

5. A heat spreader structure as claimed in claim 4 wherein the porous powder is sintered to inner surfaces of the sealed cavity to hold the porous powder in position.

6. A heat spreader structure as claimed in claim 1 wherein the base member of the vapor chamber is connected directly to the epi side of the laser and the base member is formed of at least partially of material including one of CuW, AlN, and BeO.

7. A heat spreader structure as claimed in claim 1 wherein the heat removal mechanism includes at least one thermal electric cooler.

8. A heat spreader structure as claimed in claim 4 wherein the porous powder has a particle size in a range of approximately 30 μm to approximately 200 μm.

9. A heat spreader structure as claimed in claim 8 wherein the porous powder has a particle size preferably approximately 80 μm.

10. A heat spreader structure as claimed in claim 1 wherein the wick thickness is in a range of approximately 0.1 mm to approximately 1 mm.

11. A heat spreader structure as claimed in claim 10 wherein the wick thickness is preferably approximately 0.4 mm with a high dry-out heat flux of ˜80 W/cm².

12. A heat spreader structure as claimed in claim 1 wherein the micro-structure includes porous powder with a relatively small particle size in a first area and porous powder with a relatively large particle size in a second area.

13. A heat spreader structure as claimed in claim 12 wherein the porous powder with a relatively small particle size has a particle size in a range of approximately 30 μm to approximately 40 μm.

14. A heat spreader structure as claimed in claim 13 wherein the porous powder with a relatively large particle size has a particle size in a range of approximately 100 μm to approximately 200 μm.

15. A heat spreader structure as claimed in claim 1 wherein the micro-structure includes one of mesh and etched channels.

16. A heat spreader structure as claimed in claim 15 wherein the one of mesh and etched channels has openings with a size in a range of approximately 30 μm to approximately 200 μm.

17. A heat spreader structure as claimed in claim 1 wherein the vapor chamber has a thickness, including the first member and the second member, in a range of approximately 2 mm to 4 mm.

18. A heat spreader structure as claimed in claim 1 wherein the one surface of the carrier material is coupled to the epi side of the laser and the carrier material has a coefficient of thermal expansion substantially matching the coefficient of thermal expansion of the epi side of the laser.

19. A heat spreader structure, the structure comprising:
a high power laser including an epi side and an emitting facet;
a vapor chamber including a housing defining an inner vapor cavity and a wick positioned in the vapor cavity to define an evaporation area on one side of the cavity, a condensation area on an opposite side of the cavity, a space between the evaporation area and the condensation area and fluid communication between the condensation area and the evaporation area, the wick including a micro-structure;
the epi side of the laser being coupled to the one side of the vapor chamber, at least a portion of the one side of the vapor chamber coupled to the laser being formed of material having a coefficient of thermal expansion substantially matching the coefficient of thermal expansion of the epi side of the laser; and
heat removal mechanism coupled to the opposite side of the cavity.

20. A heat spreader structure as claimed in claim 19 and further including a carrier with one side attached to the epi side of the laser and an opposite side attached to the one side of the vapor chamber, the carrier being formed of material substantially matching the coefficient of thermal expansion of the laser.

21. A heat spreader structure as claimed in claim 19 wherein the carrier is a strip of material, and the material includes one of CuW, AlN, and BeO.

22. A heat spreader structure as claimed in claim 19 wherein the housing of the vapor chamber includes a base member and a mating cover defining a sealed cavity therebetween, an inner surface of the base member defining the evaporation area and an outer or opposed surface adjacent the evaporation area defining the one side of the cavity, an inner surface of the cover defining the condensation area and an outer or opposed surface adjacent the condensation area defining the opposite side of the cavity, the wick including a first micro-structure overlying the inner surface of the base member, a second micro-structure overlying the inner surface of the cover and a third micro-structure positioned in fluid communication with the first micro-structure and the second micro-structure.

23. A heat spreader structure as claimed in claim 22 wherein the first micro-structure, the second micro-structure, and the third micro-structure include porous powder sintered to inner surfaces of the sealed cavity to hold the porous powder in position.

24. A thin form factor vapor chamber for use in a heat spreader structure the vapor chamber comprising:
a housing of the vapor chamber including a first member and a second member defining a sealed cavity therebetween, the first member being designed to have a heat source coupled thereto;
an inner surface of the first member, adjacent the heat source, defining an evaporation region within the vapor chamber;
an inner surface of the second member at least partially defining a condensation area within the vapor chamber; and
a wick including a first layer of porous powder overlying the inner surface of the first member, a second layer of porous powder overlying the inner surface of the second member and a third layer of porous powder positioned in fluid communication with the first layer and the second layer, and a space defined between the first, the second, and the third layers.

25. A thin form factor vapor chamber as claimed in claim 24 wherein the porous powder is sintered to inner surfaces of the housing to hold the porous powder in position.

26. A thin form factor vapor chamber as claimed in claim 24 wherein the porous powder has a particle size in a range of approximately 30 μm to approximately 200 μm.

27. A thin form factor vapor chamber as claimed in claim 26 wherein the porous powder has a particle size preferably approximately 80 μm.

28. A thin form factor vapor chamber as claimed in claim 24 wherein the wick thickness is in a range of approximately 0.1 mm to approximately 1 mm.

29. A thin form factor vapor chamber as claimed in claim 28 wherein the wick thickness is preferably approximately 0.4 mm with a high dry-out heat flux of ˜80 W/cm².

30. A thin form factor vapor chamber as claimed in claim 24 wherein the wick includes porous powder with a relatively small particle size in a first area and porous powder with a relatively large particle size in a second area.

31. A thin form factor vapor chamber as claimed in claim 30 wherein the wick porous powder with a relatively small particle size has a particle size in a range of approximately 30 μm to approximately 40 μm.

32. A thin form factor vapor chamber as claimed in claim 31 wherein the wick porous powder with a relatively large particle size has a particle size in a range of approximately 100 μm to approximately 200 μm.

33. A thin form factor vapor chamber as claimed in claim 24 wherein the vapor chamber has a thickness, including the first member and the second member, in a range of approximately 2 mm to 4 mm.
